(19) United States
(12) Patent Application Publication
(10) Pub. No.: US 2020/0191919 A1
(43) Pub. Date: Jun. 18, 2020

(54) TIME-OF-FLIGHT OPTICAL SYSTEMS INCLUDING A FRESNEL SURFACE

(71) Applicant: STMicroelectronics (Research & Development) Limited, Buckinghamshire (GB)

(72) Inventors: Thineshwaran GOPAL KRISHNAN, Edinburgh (GB); Christopher TOWNSEND, Edinburgh (GB)

(21) Appl. No.: 16/217,897

(22) Filed: Dec. 12, 2018

(51) Int. Cl. G01S 7/481; G02B 3/08; G02B 5/28; H01L 31/0232; G01S 7/484; G01S 7/486; G02B 5/20; G01S 17/10

(52) U.S. Cl. CPC G01S 7/4816; G02B 3/08; G02B 5/28; G01S 17/10; G01S 7/484; G01S 7/4863; G02B 5/208; H01L 31/02327

(57) ABSTRACT

In various embodiments, the present disclosure provides devices, time-of-flight sensors, and optical sensor packages. One such device includes a light sensor, a first lens, and a second lens. The first lens is positioned along a light receiving path of the light sensor, and the first lens has a first surface and a second surface opposite the first surface. The second lens is positioned along the light receiving path and positioned between the first lens and the light sensor. The second lens has a third surface facing the second surface of the first lens and a fourth surface opposite the third surface. The fourth surface faces the light sensor. At least one of the first, second, third, and fourth surfaces is a Fresnel surface.

### BACKGROUND

### Technical Field

The present disclosure generally relates to optical systems having one or more optical lenses, and more particularly, to time-of-flight sensors having one or more optical lenses.

### Description of the Related Art

Ranging devices, such as time-of-flight (TOF) sensors, are typically used to detect the distance to nearby objects and are able to do so without physically touching the object. Conventional time-of-flight sensors may be used for object detection, proximity detection, and further may be used to determine an actual range or distance from the device to a detected object. Such devices may be utilized in various electronic devices, such as cameras, phones, vehicles, machinery, and other devices for detecting the distance to nearby objects.

Conventional TOF sensors or devices typically include a light-emitting device (e.g., a laser or a light emitting diode (LED)), a return or target sensor array, a reference sensor array, and circuitry for driving an output light emission and for processing signals received by the return and reference sensor arrays. The return and reference sensor arrays may be single-photon avalanche diode (SPAD) arrays.

Generally described, the light-emitting device emits radiation into an image scene. Some portion of the emitted radiation is reflected off of an object in the image scene and back toward the return sensor array. Another portion of the emitted radiation is reflected by an internal optical barrier, and this reflected radiation is received by the reference sensor array. The return and reference arrays generate respective electrical signals indicative of the received radiation, which is transmitted to the processing circuitry (e.g., a readout circuit) which determines the distance to the object based on a difference in time in receiving the signals from the return and reference sensor arrays.

### BRIEF SUMMARY

The present disclosure is generally directed to optical systems including two optical lenses, with at least one surface of the two lenses being a Fresnel surface. Such optical systems may be particularly advantageous in TOF sensors. TOF sensors may include optical elements, for example, to receive the reflected radiation and focus it on the return sensor array. Two-lens optical systems utilizing conventional curved lenses, however, are difficult to design, particularly for optical devices having a large field of view. Moreover, while three-lens systems utilizing conventional curved lenses provide good optical characteristics for imaging applications, including for TOF sensor applications, such three-lens systems add cost and increase complexity during manufacturing, assembly, testing, and the like, as compared to two-lens systems. On the other hand, the optical performance of two-lens systems utilizing conventional curved lenses is significantly degraded as compared to three-lens systems, and may not be suitable for use in certain applications such as TOF sensors.

However, by making at least one surface of a two-lens optical system into a Fresnel surface, the inventors of the present disclosure have discovered that the optical performance is significantly improved, and may be particularly advantageous for use in TOF sensors. While the present disclosure generally describes two-lens systems including a Fresnel surface, embodiments provided herein are not limited to two-lens systems. In some embodiments, optical systems including three or more than three lenses are provided and include at least one Fresnel surface.

In one embodiment, the present disclosure provides a device that includes a light sensor, a first lens, and a second lens. The first lens is positioned along a light receiving path of the light sensor, and the first lens has a first surface and a second surface opposite the first surface. The second lens is positioned along the light receiving path and positioned between the first lens and the light sensor. The second lens has a third surface facing the second surface of the first lens and a fourth surface opposite the third surface. The fourth surface faces the light sensor. At least one of the first, second, third, and fourth surfaces is a Fresnel surface.

In another embodiment, the present disclosure provides a time-of-flight (TOF) sensor that includes a light-emitting device, a light sensor, and an optical lens system. The light-emitting device, in operation, transmits an optical pulse. The light sensor, in operation, receives a reflected portion of the optical pulse. The optical lens system is positioned in a light receiving path of the light sensor, and includes a first lens and a second lens. The first lens has a first surface and a second surface opposite the first surface. The second lens is positioned between the first lens and the light sensor. The second lens has a third surface facing the second surface of the first lens and a fourth surface opposite the third surface. The fourth surface faces the light sensor. At least one of the first, second, third, and fourth surfaces is a Fresnel surface.

In yet another embodiment, the present disclosure provides an optical sensor package that includes a substrate, a light-emitting device coupled to the substrate, an image sensor coupled to the substrate, a first lens, and a second lens. The first lens is positioned along a light receiving path of the image sensor, and the first lens has a first surface and a second surface opposite the first surface. The second lens is positioned along the light receiving path and positioned between the first lens and the image sensor. The second lens has a third surface facing the second surface of the first lens and a fourth surface opposite the third surface. The fourth surface faces the sensor die. At least one of the first, second, third, and fourth surfaces is a Fresnel surface.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements are arbitrarily enlarged and positioned to improve drawing legibility. Further, the particular shapes of the elements as drawn are not necessarily intended to convey any information regarding the actual shape of the particular elements, and have been solely selected for ease of recognition in the drawings.

FIG. 1 is a block diagram illustrating a time-of-flight (TOF) sensor device, in accordance with one or more embodiments of the present disclosure.

FIG. 2A is a diagram illustrating an example 3-lens optical system, with each of the three lenses having conventional surfaces.

FIG. 2B is a plot showing the focus shift with respect to the modulus of the optical transfer function of various optical paths of incident light through the 3-lens system of FIG. 2A.

FIG. 3A is a diagram illustrating an example 2-lens optical system, with each of the two lenses having conventional surfaces.

FIG. 3B is a plot showing the focus shift with respect to the modulus of the optical transfer function of various optical paths of incident light through the 2-lens system of FIG. 3A.

FIG. 4A is a diagram illustrating a 2-lens optical system, in which two surfaces of each of the lenses are Fresnel surfaces, in accordance with one or more embodiments of the present disclosure.

FIG. 4B is a plot showing the focus shift with respect to the modulus of the optical transfer function of various optical paths of incident light through the 2-lens system of FIG. 4A, in accordance with one or more embodiments.

FIG. 5A is a diagram illustrating a 2-lens optical system having one Fresnel surface and the remaining lens surfaces are conventional curved surfaces, in accordance with one or more embodiments of the present disclosure.

FIG. 5B is a plot showing the focus shift with respect to the modulus of the optical transfer function of various optical paths of incident light through the 2-lens system of FIG. 5A, in accordance with one or more embodiments.

FIG. 6A is a top view of an optical sensor package, in accordance with one or more embodiments.

FIG. 6B is a cross-sectional view of the optical sensor package of FIG. 6A, taken along the line A-A′.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known structures associated with portable electronic devices and head-worn devices, have not been shown or described in detail to avoid unnecessarily obscuring descriptions of the embodiments.

Throughout the specification and claims which follow, the word “comprise” and variations thereof, such as, “comprises” and “comprising” are to be construed in an open, inclusive sense, that is, as “including, but not limited to.”

Reference throughout this specification to “one embodiment” or “an embodiment” means that a particular feature, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is, as meaning “and/or” unless the content clearly dictates otherwise.

The headings and Abstract of the Disclosure provided herein are for convenience only and do not interpret the scope or meaning of the embodiments.

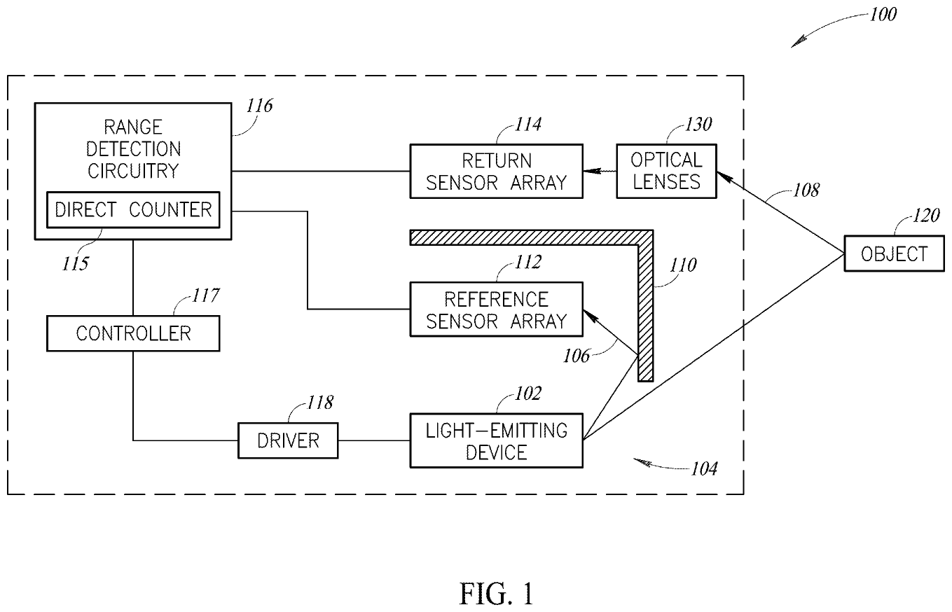

Turning now to FIG. 1, illustrated therein is a block diagram illustrating a time-of-flight (TOF) sensor device 100, in accordance with one or more embodiments of the present disclosure.

As shown in FIG. 1, the TOF sensor device 100 includes a light-emitting device 102 for generating and transmitting an optical pulse 104 into an image scene, which may contain an object 120. In one or more embodiments, the light-emitting device 102 is a laser, which may be, for example, a vertical cavity surface emitting laser (VCSEL).

An optical barrier 110 is included in the TOF range detection device 100, and reflects a first portion 106 of the optical pulse toward a reference sensor array 112, which may be, for example, a single-photon avalanche diode (SPAD) array. Other light sensors may be employed as the reference sensor array 112 in various embodiments, including, for example, avalanche diodes, charge-coupled device (CCD) or CMOS imagers. A second portion 108 of the optical pulse 104 is reflected off of the object 120 in the image scene, and is received at a return sensor array 114, which may also be a SPAD array.

The return sensor array 114 may include, for example, an array of between four and several hundred SPAD cells. As will be appreciated by those skilled in the art, SPAD arrays can be used for a variety of applications, including for ranging, for 2D or 3D gesture recognition and for 3D imaging. Each SPAD cell in the return sensor array 114 will provide an output pulse or detectable SPAD event when a photon in the form of the reflected second portion 108 of the optical pulse 104 is detected by that cell, and by monitoring these SPAD events an arrival time of the return pulse can be estimated or detected by the range detection circuitry 116.

The reference sensor array 112 may be, for example, of the same dimensions or of smaller dimensions than the return sensor array 114, and receives an internal reflection (e.g., reflected by the optical barrier 110) 106 of the transmitted optical pulse 104. In some embodiments, the reference sensor array 112 is a mono-dimensional array, for example, having only a row or column of SPAD cells.

The range detection circuitry 116 is coupled to the return sensor array 114 and the reference sensor array 112 and estimates the distance between the TOF sensor device 100 and the object 120 in the image scene against which the optical pulses reflect. For example, the range detection circuitry 116 may estimate the delay between each transmitted optical pulse 104 and the return optical pulse 108 received by the return sensor array 114 in order to provide a range estimate in the form of the detected distance to the object 120. The range detection circuitry 116 determines the time of flight based upon the difference between the transmission time of the transmitted optical pulse 104 and the arrival time of the returned optical pulse 108. The range detection circuitry 116 utilizes suitable circuitry, such as time-to-digital converters or time-to-analog converters that generate an output indicative of a time difference that may then be used to determine the time of flight of the transmitted optical pulse 104 and thereby the distance to the object 120, as will be appreciated by those skilled in the art.

In one or more embodiments, the range detection circuitry 116 includes a digital counter 115, which counts a number of photons received at the return sensor array 114 and the reference sensor array 112 within preset windows or bins of time. Then, by analysis of the photon counts received at the return sensor array 114 and the reference sensor array 112, the range detection circuitry 116 may determine a distance to the object.

The TOF range detection device 100 further includes a driver 118 that generates a driving signal for driving the light-emitting device 102, e.g., by specifying or otherwise controlling an output power of the optical pulse 104 generated by the light-emitting device 102. The driver 118 may be controlled by a controller 117 that is coupled to the range detection circuitry 116 and the driver 118.

The TOF sensor device 100 further includes optical lenses 130. The optical lenses 130 receive the reflected second portion 108 of the optical pulse, and focus the reflected second portion 108 on the reference sensor array 112. As will be discussed in further detail herein, the optical lenses 130 may be an optical system having two or more lenses, with one or more surfaces of the lenses being a Fresnel surface.

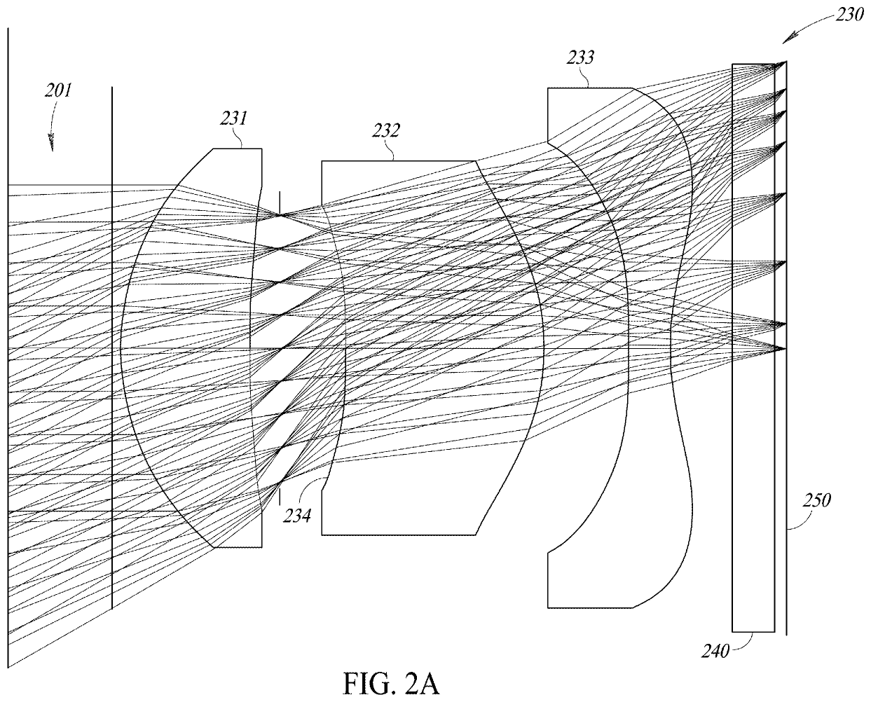

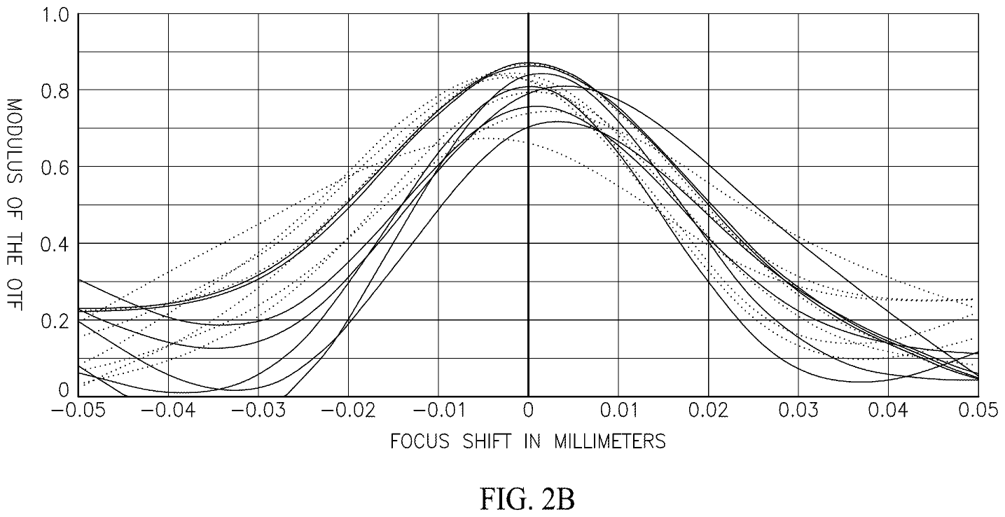

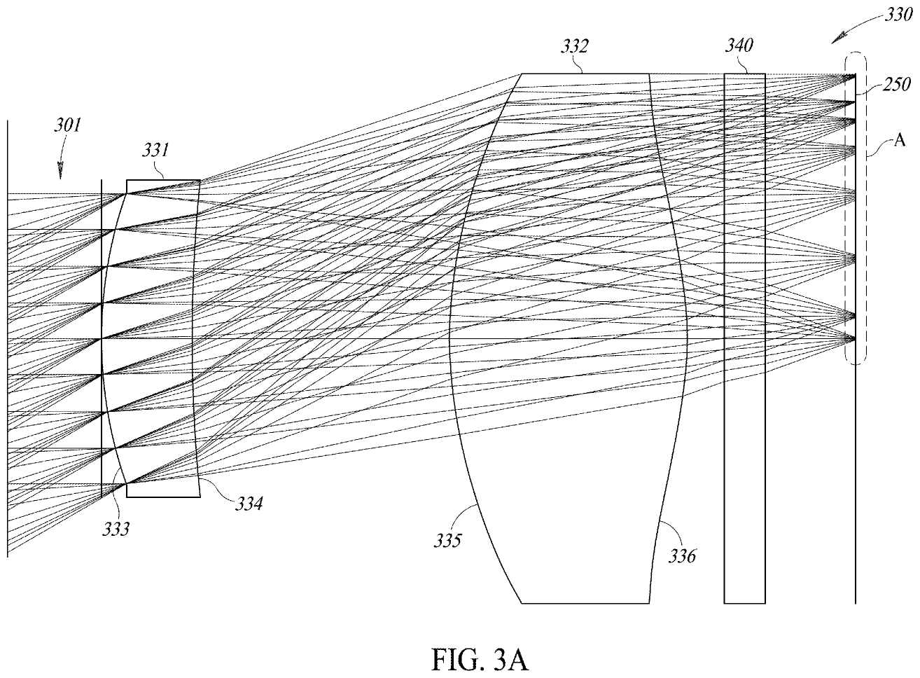

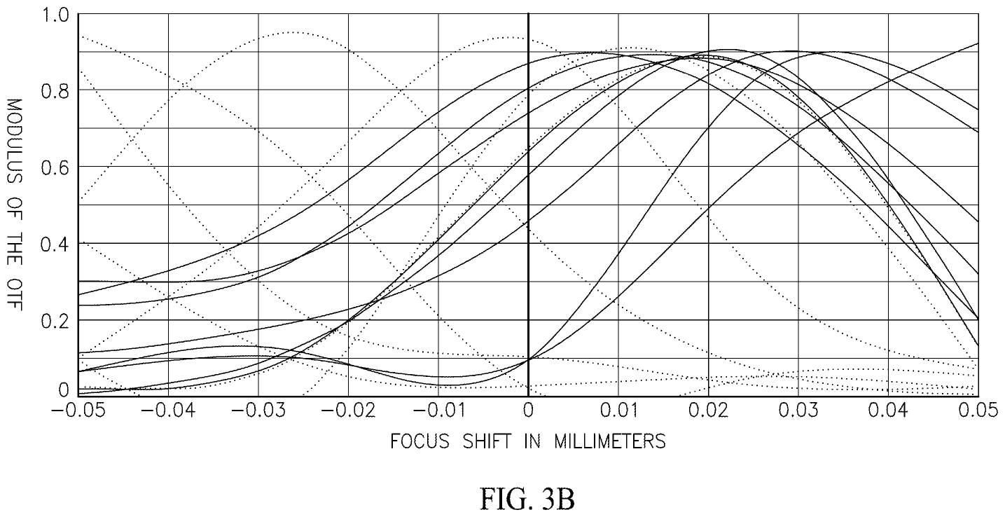

FIGS. 2A, 2B, 3A, and 3B are provided to demonstrate differences between a 3-lens optical system having conventional (i.e., non-Fresnel) surfaces and a 2-lens optical system having conventional surfaces, as will be discussed in further detail below.

FIG. 2A illustrates an example 3-lens optical system 230, with each of the three lenses having conventional (i.e., non-Fresnel) surfaces.

The 3-lens system 230 includes a first lens 231, a second lens 232, and a third lens 233, each of which have opposite surfaces that are conventional curved optical surfaces. Light 201 is received by the system 230 and directed through the first, second, and third lenses 231, 232, 233 toward a sensor surface 250. The light 201 may be, for example, the return optical pulse 108 (see FIG. 1) that is reflected off of an object 120. The sensor surface 250 may be a surface of the return sensor array 114. A filter 240, such as a bandpass filter, may be positioned between the third lens 233 and the sensor surface 250.

The light 201 is shown as many lines having different positions and/or angles, which represents some of the various optical paths for incident light that may be received by the system 230. FIG. 2A illustrates light 201 being focused to only an upper half of the sensor surface 250; however, it will be readily appreciated that light 201 may include further optical paths which would be focused to the lower half of the sensor surface 250, e.g., in a symmetrical way.

FIG. 2B is a plot showing the focus shift (x-axis) with respect to the modulus of the optical transfer function (OTF) (y-axis) of the various optical paths of the incident light 201 through the 3-lens system 230. Each of the curves shown in the plot of FIG. 2B thus corresponds to a particular line or portion of the incident light 201 shown in FIG. 2A.

The modulus of the optical transfer function, which may also be known as the modulation transfer function, may be referred to herein as “MTF”. The resolution and performance of an optical lens system can be characterized by the MTF, which may generally be described as a measurement of the ability of the lens system to transfer contrast from the imaged object to an image plane (e.g., the sensor surface 250) at a specific resolution.

For the purposes of the present discussion, it should be understood that in an ideal optical lens system, all of the curves shown in FIG. 2B would have peaks that are aligned with one another at 0 focus shift along the x-axis, and that have peak values of 1.0 MTF at the 0 focus shift point. A value of 1.0 MTF (i.e., along the y-axis) indicates that the lens system perfectly renders the object, and the curves all being aligned with one another indicates that the resolution of the lenses of the optical system is perfect across the field of view.

As seen in FIG. 2B, the curved lines are closely aligned with one another, and generally have peaks that closely correspond to a 0 focus shift. Therefore, the 3-lens system 230 provides good performance in terms of accurately focusing the light 201 to the sensor surface 250, with high resolution of the lenses 231, 232, 233 across the field, and with all of the various optical paths of the light 201 being focused substantially on the same plane.

While the 3-lens system 230 of FIG. 2A provides good optical characteristics for various applications, such systems having three lenses generally are higher cost and more complex to manufacture, assemble, and test. Additionally, 3-lens optical systems may have increased image degradation as compared to 2-lens systems. However, as will be described in further detail below, 2-lens optical systems having conventional surfaces have drawbacks that may render them undesirable or even unsuitable for use in certain applications, such as TOF sensors.

FIG. 3A illustrates an example 2-lens optical system 330, with each of the two lenses having conventional surfaces.

The 2-lens system 330 includes a first lens 331 and a second lens 332, each of which have opposite surfaces that are conventional curved optical surfaces. More particularly, the first lens 331 includes a first curved surface 333 and a second curved surface 334 that is opposite to the first curved surface 333. Similarly, the second lens 332 includes a third curved surface 335 and a fourth curved surface 336 that is opposite to the third curved surface 334.

Light 301 is received by the system 330 and directed through the first and second lenses 331, 332 toward the sensor surface 250. The sensor surface 250 may be a surface of the return sensor array 114. A filter 340, such as a bandpass filter, may be positioned between the second lens 332 and the sensor surface 250.

Similar to the illustration of FIG. 2A, in FIG. 3A the light 301 is shown as being focused to only an upper half of the sensor surface 250; however, it will be readily appreciated that light 301 may include further optical paths which would be focused to the lower half of the sensor surface 250, e.g., in a symmetrical way.

FIG. 3B is a plot showing the focus shift (x-axis) with respect to the modulus of the optical transfer function (OTF) (y-axis) of the various optical paths of the incident light 301 through the 2-lens system 330. Each of the curves shown in the plot of FIG. 3B thus corresponds to a particular line or portion of the incident light 301 shown in FIG. 3A.

As seen in FIG. 3B, the curved lines are substantially out of alignment, with many or most of the curved lines having peaks that occur relatively far from the 0 focus shift point. This is also shown at region A of FIG. 3A, as the various optical paths of the light 301 are not uniformly focused on the same plane, i.e., the sensor surface 250. Instead, some portions of the light 301 are focused to a position between the sensor surface 250 and the filter 340 (i.e., a negative focus shift), while other portions of the light 301 are focused to positions past the sensor surface 250 (i.e., a positive focus shift).

As can be seen from a comparison of FIGS. 2B and 3B, the 2-lens system 330 has a significant degradation in MTF compared to the 3-lens system 230. This degradation in MTF of the 2-lens system 330 is a result of excessive field curvature and astigmatism, which at least partially account for the curved lines in FIG. 3B being out of alignment. Because the various optical paths of the light 301 are out of alignment (e.g., are not focused on a same plane), the 2-lens system 330 introduces blur spots, and has a reduced resolution as compared to the 3-lens system 230.

The optical characteristics of the 2-lens system 330 therefore may be undesirable for use in certain applications, such as TOF sensors. In particular, the aberrations of the 2-lens system 330, for example, as may be due to excessive field curvature and astigmatism, may be undesirable in TOF sensors and other imaging applications. One way to reduce these aberrations is to introduce a negative power, such as be introducing a negative optical surface or negative optical element. However, this generally means adding another lens to the optical system. For example, the 3-lens system 230 shown in FIG. 2A has a negative power surface 234 as one surface of the second lens 232.

Another way to reduce the aberrations of the 2-lens system 330, in accordance with various embodiments of the present disclosure, is to introduce one or more Fresnel surfaces into a 2-lens optical system. In a Fresnel surface, the physical curvature of an optical lens surface is made flat, or substantially flat, which results in flattened field curvature.

Fresnel lenses, i.e., a lens having one or more Fresnel surfaces, are known to those skilled in the relevant art, and are typically used in single lens systems, for example, to replace a conventional spherical or cylindrical lens with a spherical or cylindrical Fresnel lens that has a plurality of ring-shaped segments that all focus light on a single point or single line. The Fresnel lens reduces the amount of material compared to a conventional lens by dividing the lens into a plurality of annular sections. In each section, the overall thickness is decreased compared to an equivalent curved or conventional lens. The Fresnel lens, or a Fresnel surface, thus divides an otherwise continuous surface of a conventional curved lens into a set of surfaces of the same curvature, with stepwise discontinuities between them.

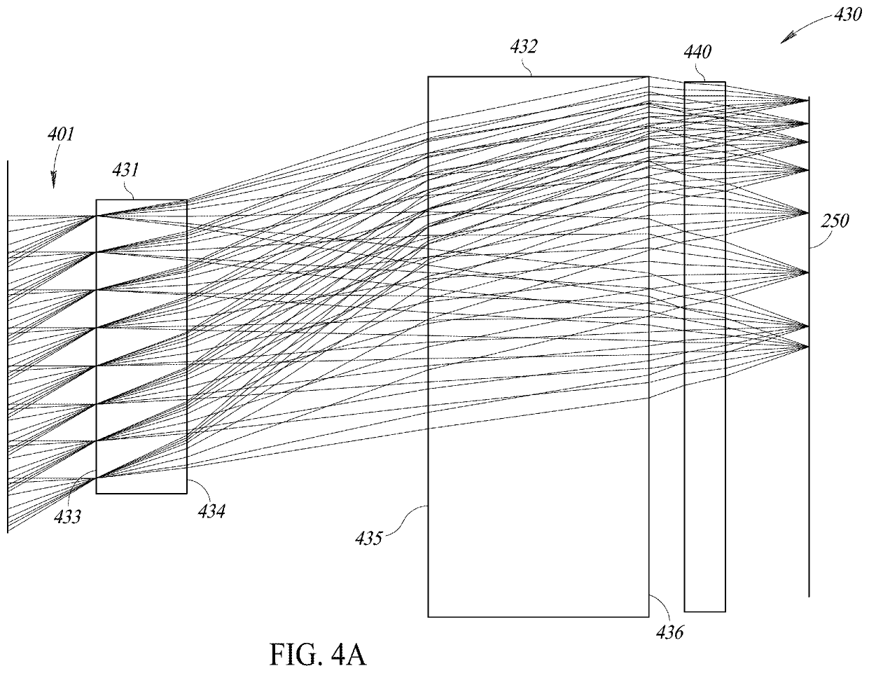

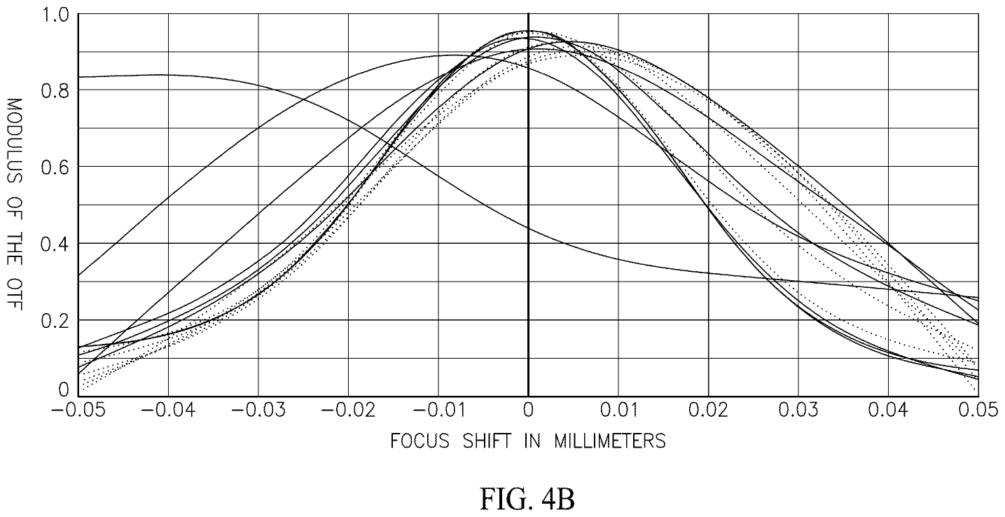

FIG. 4A illustrates a 2-lens optical system 430, in accordance with one or more embodiments of the present disclosure, in which both surfaces (e.g., front and rear) of each of the two lenses are Fresnel surfaces. Thus, the 2-lens system 430 is similar to the 2-lens system 330 of FIG. 3A, except the curved surfaces of the conventional lenses in the system 330 have been replaced by Fresnel surfaces in the 2-lens system 430.

The 2-lens system 430 includes a first lens 431 and a second lens 432. The first lens 431 includes first and second surfaces 433, 434 that are opposite one another, and each of which are Fresnel surfaces, as opposed to the conventional curved optical surfaces of the lenses in the system 330 of FIG. 3A. Similarly, the second lens 434 includes third and fourth surfaces 435, 436 that are opposite one another, and each of which are Fresnel surfaces.

Light 401 is received by the system 430 and directed through the first and second lenses 431, 432 toward the sensor surface 250. The sensor surface 250 may be a surface of the return sensor array 114. A filter 440, such as a bandpass filter, may be positioned between the second lens 432 and the sensor surface 250.

Similar to the illustration of FIG. 2A, in FIG. 4A the light 401 is shown as being focused to only an upper half of the sensor surface 250; however, it will be readily appreciated that light 401 may include further optical paths which would be focused to the lower half of the sensor surface 250, e.g., in a symmetrical way.

FIG. 4B is a plot showing the focus shift (x-axis) with respect to the modulus of the optical transfer function (OTF) (y-axis) of the various optical paths of the incident light 401 through the 2-lens system 430. Each of the curves shown in the plot of FIG. 4B thus corresponds to a particular line or portion of the incident light 401 shown in FIG. 4A.

As can be seen from a comparison of FIGS. 3B and 4B, the 2-lens system 430 including Fresnel surfaces has a significantly improved MTF compared to the 2-lens system 330 having conventional lenses with curved surfaces. For example, the curved lines in the plot shown in FIG. 4B are more closely aligned with one another and have peaks that occur closer to the 0 focus shift point than in the plot shown in FIG. 3B. Accordingly, in the system 430, the astigmatism closes and the field curvature may be flattened, as compared to the excessive field curvature and astigmatism of the 2-lens system 330 having conventional lenses.

While the 2-lens system 430 including Fresnel surfaces provides significant improvements in optical performance as compared to the 2-lens system 330 of FIG. 3A, the Fresnel surfaces may introduce excessive stray light reflections, e.g., due to the faceted and discontinuous nature of the Fresnel surfaces. Accordingly, having all four surfaces (e.g., surfaces 433 to 436) being Fresnel surfaces may be undesirable in various applications, including TOF sensor applications. Instead, in one or more embodiments, a 2-lens optical system for a TOF sensor may preferably include at least one conventional or curved surface, and in some embodiments, a 2-lens optical system for a TOF sensor may include one Fresnel surface and three non-Fresnel or conventional curved surfaces, as will be described in further detail below.

In order to determine which surface of a 2-lens optical system to be made a Fresnel surface, the inventors of the present disclosure developed models and conducted a variety of optical experiments using the 2-lens system 330 shown in FIG. 3A and discovered that the third and fourth surfaces 335, 336 of the second lens 332 accounted for most of the optical aberrations of the system 330. In particular, the third and fourth surfaces 335, 336 accounted for the largest errors in terms of astigmatism and field curvature of the 2-lens system 330. The fourth surface 336 accounted for larger errors in both astigmatism and field curvature than the third surface 335; however, the third surface 335 has the highest surface curvature and steepest ray grazing angle, which are typically not desirable in lens design. Accordingly, replacing either or both of the third and fourth surfaces 335, 336 with Fresnel surfaces (e.g., with surfaces 435, 436 of the system 430 shown in FIG. 4A) reduces optical aberrations and improves the performance of a 2-lens optical system.

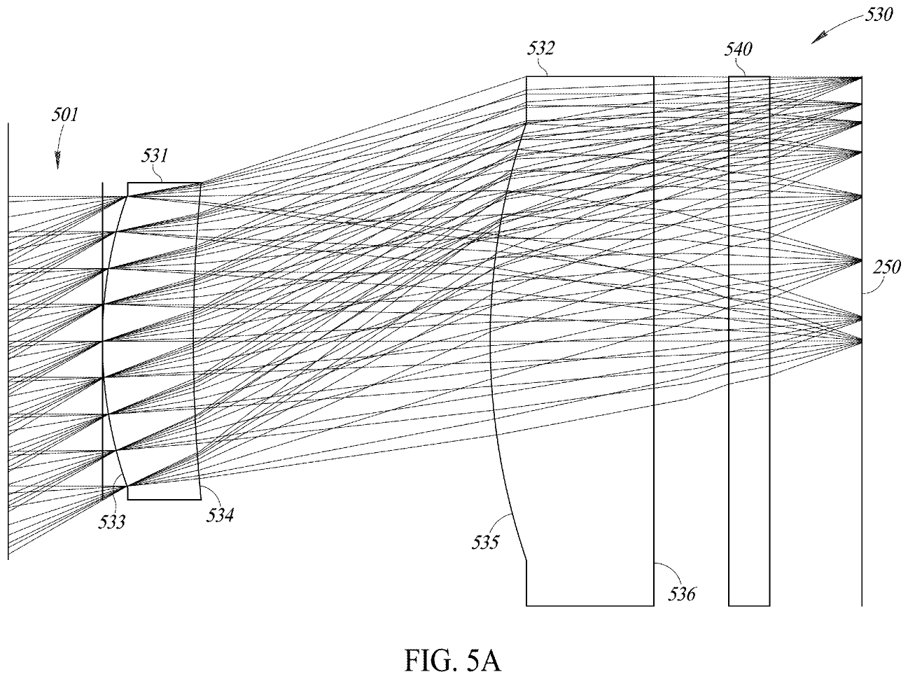

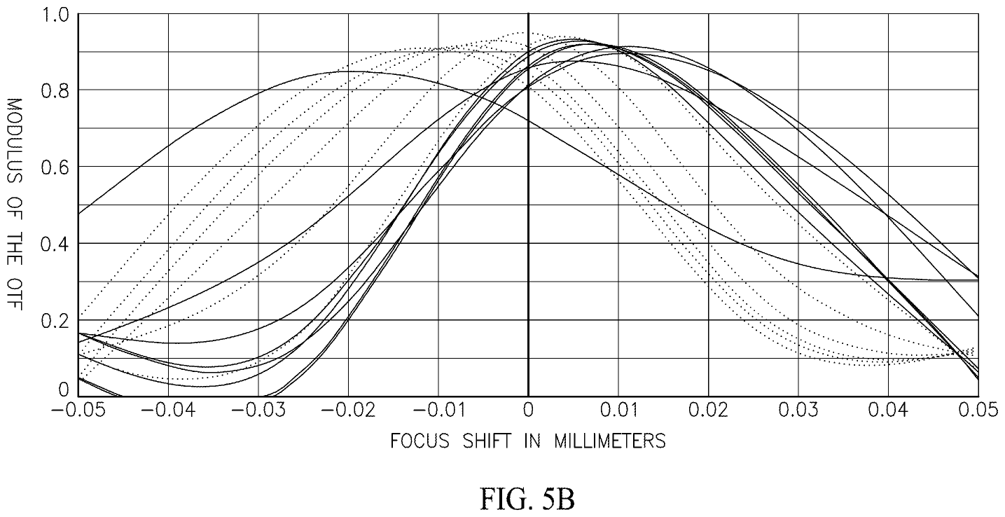

FIG. 5A illustrates a 2-lens optical system 530, in accordance with one or more embodiments of the present disclosure. The system 530 includes a first lens 531 having first and second surfaces 533, 534, and a second lens 532 having third and fourth surfaces 535, 536. The first lens 531 may be a conventional optical lens, with both the first and second surfaces 533, 534 being curved surfaces. At least one of the third and fourth surfaces 535, 536 of the second lens 532 is a Fresnel surface. As shown in FIG. 5A, the fourth surface 536 may be a Fresnel surface, while the third surface 535 may be a curved surface. However, in various embodiments, either or both of the third and fourth surfaces 535, 536 may be Fresnel surfaces.

FIG. 5B is a plot showing the focus shift (x-axis) with respect to the modulus of the optical transfer function (OTF) (y-axis) of the various optical paths of the incident light 501 through the 2-lens system 530. Each of the curves shown in the plot of FIG. 5B thus corresponds to a particular line or portion of the incident light 501 shown in FIG. 5A.

As can be seen from a comparison of FIGS. 3B and 5B, the 2-lens system 530 having a Fresnel surface as the fourth surface 536 of the second lens 532 has a significantly improved MTF compared to the 2-lens system 330 having conventional lenses with curved surfaces for both of the first and second lenses 331, 332. For example, the curved lines in the plot shown in FIG. 5B are more closely aligned with one another and have peaks that occur closer to the 0 focus shift point than in the plot shown in FIG. 3B. Accordingly, in the system 530, the errors due to astigmatism and field curvature are significantly reduced as compared to the 2-lens system 330 having conventional lenses. The 2-lens system 530 therefore has improved performance as compared to the 2-lens system 330 having conventional curved lenses, and the improvements in performance include improvements in terms of reduced sensitive to tolerance errors, as the curved surfaces of the 2-lens system 330 would otherwise transmit these errors.

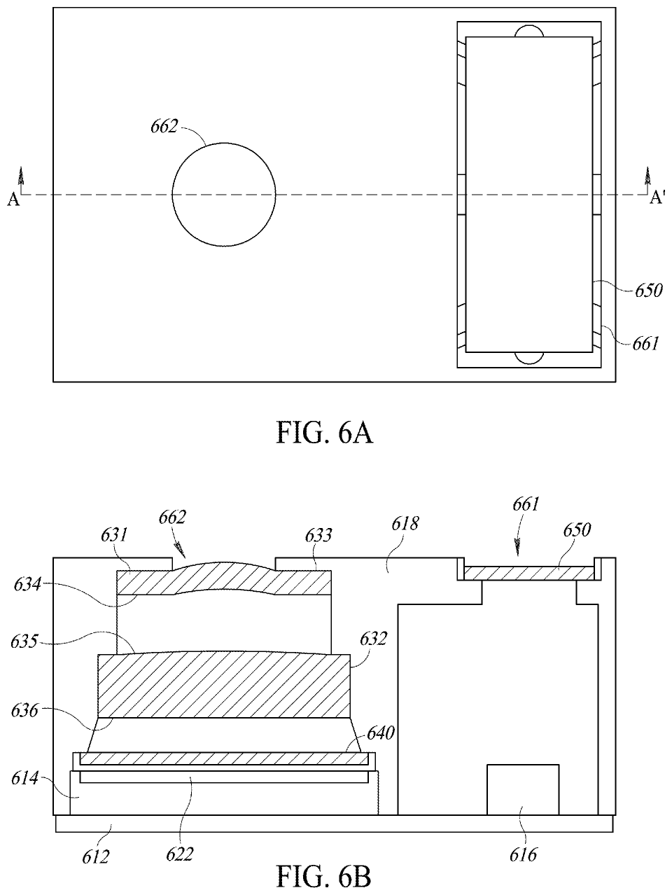

FIG. 6A is a top view of a TOF sensor package 610 according to one or more embodiments of the present disclosure. FIG. 6B is a cross-sectional view of the TOF sensor package 610, taken along the line A-A′. The TOF sensor package 610 may be the same as or substantially similar to the TOF sensor device 100 shown in FIG. 1, and may include any or all of the various features shown in the block diagram of FIG. 1.

As best shown in FIG. 6B, the optical sensor package 610 may include a substrate 612, a sensor die 614, a light-emitting device 616, first and second lenses 631, 632, and a cap 618.

Generally described, the substrate 612 includes one or more insulative and conductive layers. An upper surface of the substrate 612 may include conductive pads for electrically coupling the substrate 612 to the sensor die 614, and a lower surface of the substrate 612 may include conductive pads or lands for electrically coupling the substrate 612 and/or the sensor die 614 to external circuitry or components, such as an external circuit board. Conductive traces and/or vias may be formed in the substrate 612, and may electrically couple pads on the upper surface with one or more lands on the lower surface of the substrate 612. The lower surface of the substrate 612 forms an outer surface of the TOF sensor package 610.

The sensor die 614 is secured to the upper surface of the substrate 612, such as by an adhesive material, which may be any material suitable for securing the sensor die 614 to the substrate 612, such as tape, paste, glue, or any other suitable material.

The sensor die 614 is made from a semiconductor material, such as silicon, and includes one or more electrical components, such as integrated circuits. The integrated circuits may be analog or digital circuits implemented as active devices, passive devices, conductive layers, and dielectric layers formed within the die and electrically interconnected according to the electrical design and function of the die. In particular, the sensor die 614 may include electrical components that form an Application Specific Integrated Circuit (ASIC). Thus, the sensor die 614 includes circuitry to send, receive, and analyze electrical signals as is well known in the art.

An image sensor 622 is formed in or otherwise coupled to the upper surface of the sensor die 614. The image sensor 622 may be or otherwise correspond to the return sensor array 114 shown in the block diagram of FIG. 1.

The first and second lenses 631, 632 correspond to the optical lenses 130 shown in the block diagram of FIG. 1. Accordingly, the lenses 631, 632 may receive a reflected portion of light that is emitted by the light-emitting device 616, and focus the received light onto the image sensor 622. Each of the lenses 631, 632 may be secured to the cap 618 by any suitable means, including, for example, by an adhesive.

The first lens 631 has opposing first and second surfaces 633, 634, and the second lens 632 has opposing third and fourth surfaces 635, 636. At least one of the first through fourth surfaces 633 to 636 is a Fresnel surface, and in some embodiments, more than one of the first through fourth surfaces 633 to 636 may be Fresnel surfaces. For example, any one or more of the first through fourth surfaces 633 to 636 may be a Fresnel surface respectively corresponding to the first through fourth surfaces 433 to 436 of the 2-lens system 430 shown in FIG. 4A.

In some embodiments, only one of the first through fourth surfaces 633 to 636 is a Fresnel surface, while the other surfaces are conventional, curved optical surfaces. For example, the first and second lenses 631, 632 of the TOF sensor package 610 may correspond to the first and second lenses 531, 532 of the 2-lens system 530 shown in FIG. 5A. In such embodiments, any of the first through fourth surfaces 633 to 636 may be a Fresnel surface; however, as previously described herein, it may be advantageous to have one or both of the surfaces of the second lens 632 as a Fresnel surface.

The first and second lenses 631, 632 may be formed of any optically transparent or transmissive materials, including glass, plastics, and the like. In some embodiments, the lenses 631, 632 are plastic lenses which are formed by injection molding.

An optical filter 640 may be positioned between the second lens 632 and the image sensor 622. The optical filter 640 may be a bandpass filter that only allows light within a particular range of wavelengths to pass through, while filtering out light outside of the particular wavelength range. In one embodiment, the optical filter 640 is a bandpass filter that passes light having wavelengths of 940 nm±20 nm. That is, the filter 640 may pass light having a wavelength within a range of 920 nm to 960 nm, inclusive.

The light-emitting device 616 may emit radiation in response to an electrical signal received from the sensor die 614, and the image sensor 622 may receive the reflected radiation, after passing through the lenses 631, 632 and the filter 640, and provide electrical signals to the sensor die 614 for processing. The light-emitting device 616 corresponds to the light-emitting device 102 shown in the block diagram of FIG. 1. In various embodiments, the light-emitting device 616 may be a vertical cavity surface emitting laser (VCSEL) or a light-emitting diode (LED), e.g., an infrared LED. In some embodiments, the light-emitting device 616 emits light having a wavelength of about 940 nm.

The light-emitting device 616 is secured to the upper surface of the substrate 612 using, for example, an adhesive material. The light-emitting device 616 is electrically coupled to the sensor die 614 (e.g., directly electrically coupled to the sensor die 614 and/or indirectly coupled to the sensor die 614 through the substrate 612) and is configured to receive electrical signals, such as a power signal from the sensor die 614, and in response to receiving the signal, to emit the radiation at a particular frequency or wavelength range.

The cap 618 has outer sidewalls, an upper surface, and an inner wall, as shown for example in FIG. 6B. First and second openings 661, 662 extend through the upper surface of the cap 618. The first opening 661 allows the light emitted by the light-emitting device 616 to exit the TOF sensor package 610, while the second opening 662 allows a portion of the emitted light that is reflected by an object to enter the TOF sensor package 610, where it is focused by the lenses 631, 632 onto the image sensor 622. The inner wall optically separates the light-emitting device 616 from the image sensor 622 within the TOF sensor package 610, so that the image sensor 622 receives only reflected portions of the emitted light. The cap 618 may thus serve as the optical barrier 110 as shown in the block diagram of FIG. 1. The cap 618 may be attached to the substrate 612 by any suitable means, including, for example, by an adhesive.

In some embodiments, the TOF sensor package 610 may further include a light transmissive element 650 positioned over the light-emitting device 616. The light transmissive element 650 may be positioned in a first opening 661 of the cap 618. The light transmissive element 650 may be attached to the cap 618 by any suitable means, including an adhesive, and the light transmissive element 650 may prevent moisture, particles or other contaminants from entering the TOF sensor package 610 through the first opening 661 of the cap 618.

Although not shown in FIG. 6B, the TOF sensor package 610 may further include a reference sensor, such as the reference sensor array 112 of the block diagram of FIG. 1. The reference sensor may be formed in or otherwise coupled to the substrate 612, and may be optically separated from the image sensor 622 by the inner wall of the cap 618.

Additional components shown in the block diagram of FIG. 1 may be included in the TOF sensor package 610, including, for example, the range detection circuitry 116, digital counter 115, controller 117, and driver 118. Such components may be formed in or electrically coupled to the substrate 612 and/or the sensor die 614.

In operation, the ASIC of the sensor die 614 is configured to cause the light-emitting device 616 to emit light through the first opening 661. The light is reflected by a nearby object and travels through the second opening 662, and is focused by the first and second lenses 631, 632 onto the image sensor 622, which senses the received light. The ASIC of the sensor die 614 receives the signals from the image sensor 622 and is configured to process signals generated by the image sensor 622 upon receiving the reflected light.

As described herein, the present disclosure provides various embodiments which may be suitable for use in various applications, including, for example, in TOF sensors. The embodiments provided herein, which include optical systems having one or more Fresnel surfaces, provide several advantages over optical systems having lenses with conventional curved surfaces. For example, the optical systems including at least one Fresnel surface, as provided herein, facilitate a reduction in a total number of optical elements or lenses in an assembly. This is because the optical systems including one or more Fresnel surfaces provided herein have improved optical performance, and may have an optical performance that is comparable to that of a conventional optical system having one additional lens.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a light sensor;
a first lens positioned along a light receiving path of the light sensor, the first lens having a first surface and a second surface opposite the first surface;
a second lens positioned along the light receiving path and positioned between the first lens and the light sensor, the second lens having a third surface facing the second surface of the first lens and a fourth surface opposite the third surface, the fourth surface facing the light sensor,
wherein at least one of the first, second, third, and fourth surfaces is a Fresnel surface.

2. The device of claim 1, further comprising an optical filter between the second lens and the light sensor.

3. The device of claim 2 wherein the optical filter is a bandpass filter.

4. The device of claim 3 wherein the bandpass filter is configured to block light having a wavelength outside of a range from 920 nm to 960 nm.

5. The device of claim 1 wherein the light sensor comprises an array of single-photon avalanche diodes.

6. The device of claim 1 wherein more than one of the first, second, third, and fourth surfaces are Fresnel surfaces.

7. The device of claim 1 wherein the fourth surface is a Fresnel surface.

8. The device of claim 7 wherein the third surface is a Fresnel surface.

9. The device of claim 1, further comprising a third lens positioned along the light receiving path of the light sensor.

10. A time-of-flight (TOF) sensor, comprising:
a light-emitting device which, in operation, transmits an optical pulse;
a light sensor which, in operation, receives a reflected portion of the optical pulse; and
an optical lens system positioned in a light receiving path of the light sensor, the optical lens system including:
a first lens having a first surface and a second surface opposite the first surface, and
a second lens positioned between the first lens and the light sensor, the second lens having a third surface facing the second surface of the first lens and a fourth surface opposite the third surface, the fourth surface facing the light sensor,
wherein at least one of the first, second, third, and fourth surfaces is a Fresnel surface.

11. The TOF sensor of claim 10 wherein the fourth surface is a Fresnel surface.

12. The TOF sensor of claim 10 wherein the third surface is a Fresnel surface.

13. The TOF sensor of claim 10 wherein the third surface and the fourth surface are Fresnel surfaces.

14. The TOF sensor of claim 10 wherein the light-emitting device comprises at least one of a vertical cavity surface emitting laser (VCSEL) and a light-emitting diode (LED).

15. The TOF sensor of claim 10, further comprising an optical bandpass filter positioned between the second lens and the light sensor.

16. The TOF sensor of claim 10, further comprising:
a reference light sensor; and
range detection circuitry which, in operation, determines a distance to an object based on signals received from the light sensor and the reference light sensor.

17. An optical sensor package comprising:
a substrate;
a light-emitting device coupled to the substrate;
an image sensor coupled to the substrate;
a first lens positioned along a light receiving path of the image sensor, the first lens having a first surface and a second surface opposite the first surface; and
a second lens positioned along the light receiving path and positioned between the first lens and the image sensor, the second lens having a third surface facing the second surface of the first lens and a fourth surface opposite the third surface, the fourth surface facing the sensor die,
wherein at least one of the first, second, third, and fourth surfaces is a Fresnel surface.

18. The optical sensor package of claim 17 wherein the light-emitting device comprises at least one of a vertical cavity surface emitting laser (VCSEL) and a light-emitting diode (LED).

19. The optical sensor package of claim 17, further comprising a cap coupled to the substrate, the cap defining a first opening over the light-emitting device and a second opening over the first lens, the second lens, and the image sensor.

20. The optical sensor package of claim 19 wherein the cap includes an inner wall that optically separates the light-emitting device from the image sensor.
